(19) United States
(12) Patent Application Publication
(10) Pub. No.: US 2006/0282724 A1
(43) Pub. Date: Dec. 14, 2006

(54) Programmatically switched hot-plug PCI slots

(75) Inventor: Daniel T. Roulo, Renton, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Microsoft Corporation, Redmond, WA (US)

(21) Appl. No.: 11/153,009

(22) Filed: Jun. 14, 2005

(51) Int. Cl. G01R 31/28; G06F 1/00

(52) U.S. Cl. 714/724; 713/300

(57) ABSTRACT

Electrically decoupling circuit boards, such as PCI cards, from a backplane bus without physically removing the circuit boards from backplane connectors is disclosed. A microprocessor controls the state of electrically controlled switches that control the application of power to the power terminals of backplane connectors. Optionally, manually operated switches also control the application of power to the power terminals of the backplane connector.

### FIELD OF THE INVENTION

The present invention relates to electrical measuring and testing, and more particularly, to circuit board measuring and testing.

### BACKGROUND OF THE INVENTION

Certain types of software modules depend on Peripheral Component Interconnect (PCI) hardware for code pathing. More specifically, many personal computers include a PCI bus that allows a number of PCI expansion boards or cards to be installed on the personal computer. Typical expansion boards or cards are circuit boards that add memory, disk drive controllers, video support, parallel and serial ports, internal modems. A sound card is another example of an expansion card.

To ensure that software modules interface correctly with a wide variety of PCI expansion cards and other circuit boards, prior to release, software modules are often tested with a plurality of circuit boards having similar features and functions but differ in design, manufacturer, vendor, configuration, or other characteristics. One way of performing such tests is to plug a plurality of circuit boards such as PCI expansion cards into a backplane. A backplane is a circuit board containing a plurality of circuit board connectors, i.e., backplane connectors. A backplane may be internal, i.e., inside of a computing device, such as a personal computer, or external, i.e., outside of a computing device and connected by a cable to the computing device. Preferably, the plurality of backplane connectors are connected to a common bus. A bus is an electrical conductor, or more normally a set of conductors, also called lines or traces, that serve as a common connection to a plurality of electrical circuits, e.g., circuit boards. In addition to signal connections, a bus often includes conductors that provide power to components, e.g., circuit boards, connected to the bus. The backplane connectors include slots into which circuit boards are “plugged.” When plugged into the slot of a backplane connector, terminals located along an edge of the circuit board contact terminals located in the slot of the backplane connector.

Plugging a plurality of circuit boards into a plurality of backplane connectors is an efficient way to simultaneously conduct tests on a plurality of circuit boards, e.g., PCI expansion cards. Unfortunately, it is often desirable to include only certain circuit boards in a test so as to prevent intercard interference, i.e., interference resulting from the cards not being tested connected to the backplane. In the past, this has required that circuit boards not being tested be removed from the backplane connectors. Removing circuit boards from backplane connectors is inconvenient, inefficient, time consuming, and may damage the circuit boards and/or backplane connectors.

What is needed is a way to prevent circuit boards connected to a backplane, but not being tested, from interfering with circuit boards connected to the backplane and being tested, without physically removing the circuit boards not being tested from the backplane connectors.

### SUMMARY OF THE INVENTION

The present invention is directed to providing methods and apparatus that allow circuit boards not being tested to remain physically connected to backplane connectors while other circuit boards connected to backplane connectors coupled to the same backplane bus are being tested. In accordance with the invention, electrically controllable switches, such as electronic switches, control power to the power supply terminals of individual backplane connectors. Preferably, the state of the electrically controllable switches are controlled by a programmable microprocessor or equivalent device.

In accordance with another aspect of the invention, in addition, or as an alternative, to electrically controllable switches controlling power to the power supply terminals of individual backplane connectors, power to the power supply terminals of individual backplane connectors is controlled by manually operable switches.

In accordance with another aspect of the invention, the backplane bus is a PCI bus.

In accordance with a further aspect of the invention, the microprocessor or equivalent device receives control instructions via a USB connection.

Embodiments of the present invention allow selected circuit boards to in effect be decoupled from a backplane without physically removing the circuit boards from backplane connectors. More specifically, the present invention provides for selectively controlling the application of power to the individual circuit boards connected to backplane connectors. Selectively controlling circuit board power allows selected circuit boards to be decoupled from the related backplane bus by placing the related switches in an open state. Selective decoupling in this manner prevents the decoupled circuit boards from interfering with the operation of the circuit boards that remain coupled to the backplane bus via their backplane connectors.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 illustrates an exemplary external PCI backplane modified in accordance with the invention connected to an exemplary computing device;

FIG. 2 is a schematic diagram of a portion of the exemplary PCI backplane modification illustrated in FIG. 1; and

FIG. 3 is a flow diagram showing how the PCI backplane modification illustrated in FIGS. 1 and 2 is controlled by software.

### DETAILED DESCRIPTION OF THE PREFERRED EMBODIMENT

Embodiments of the invention provide methods, apparatus, and computer readable medium that allows circuit boards, such as PCI cards, to be electrically “decoupled” from a backplane bus without physically removing the circuit boards from their backplane connectors. As used in this application, decoupling means the placing of a circuit board in a state that does not interfere with the effective operation, i.e., testing of circuit boards that are not “decoupled” from a backplane. Such decoupling allow circuit boards to be electronically removed from the backplane without requiring that the decoupled circuit boards be physically removed.

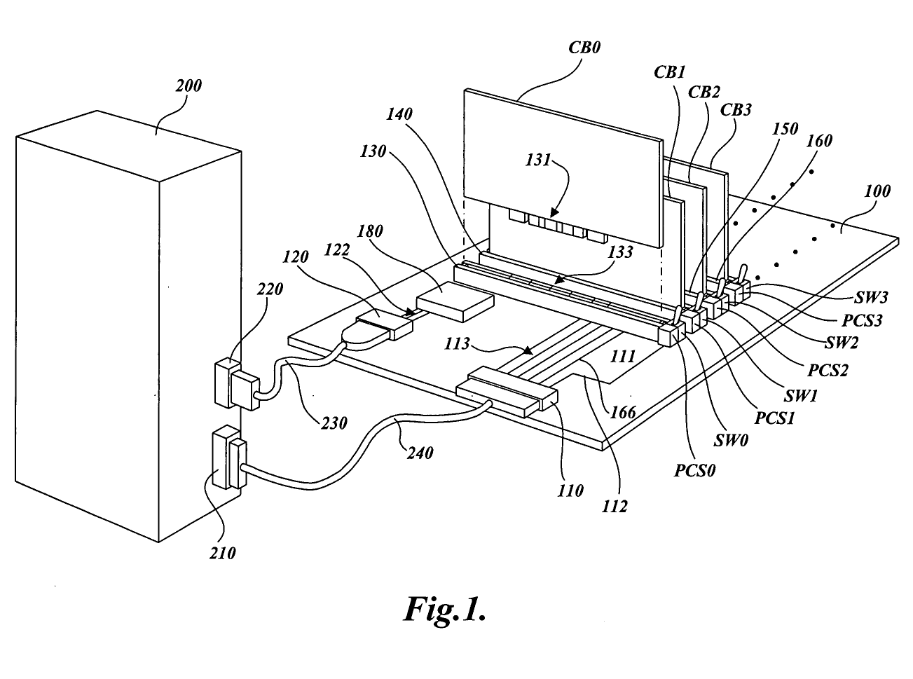

An exemplary apparatus is illustrated in FIG. 1. FIG. 1 includes an external backplane 100 connected a computing device 200 through two cables. One cable is a Personal Computer Interconnect (PCI) cable 240. PCI is an industry-standard used in servers, workstations, personal computers, and other computing devices to provide a high-speed bus connection to components internal and peripheral to a computing device. The second cable is a Universal Serial Bus (USB) cable 230. USB is an industry-standard used in servers, workstations, personal computers, and other computing devices to provide bus connections to components peripheral and internal to a computing device. Since a PCI bus includes more individual traces or lines 111 than a USB bus 122, a PCI bus is more suited to high-speed data transfer over short distances, particularly to internal components like disc drives, video circuit boards, and the like. A USB bus, having fewer lines than a PCI bus, is more suited to lower speed data transfer over longer distances, particularly to external components like keyboards, mice, and the like. Since there are many types of buses other than PCI and USB buses, the use herein of PCI and/or USB with buses, cables, etc., should be construed as exemplary and not limiting.

One end of the PCI cable 240 is connected to a PCI connector 210 included in the computing device 200, and the other end of the PCI cable 240 is connected to a PCI connector 110 mounted on the backplane 100. A plurality of backplane connectors 130, 140, 150, 160 . . . are also mounted on the backplane 100. In a conventional manner, the terminals to the backplane connectors are connected to the signal and power traces, or lines, of a PCI bus 111. For ease of illustration and because they are not significant to the invention, only a few of the signal lines or traces 113 of the PCI bus 111 are shown in FIG. 1.

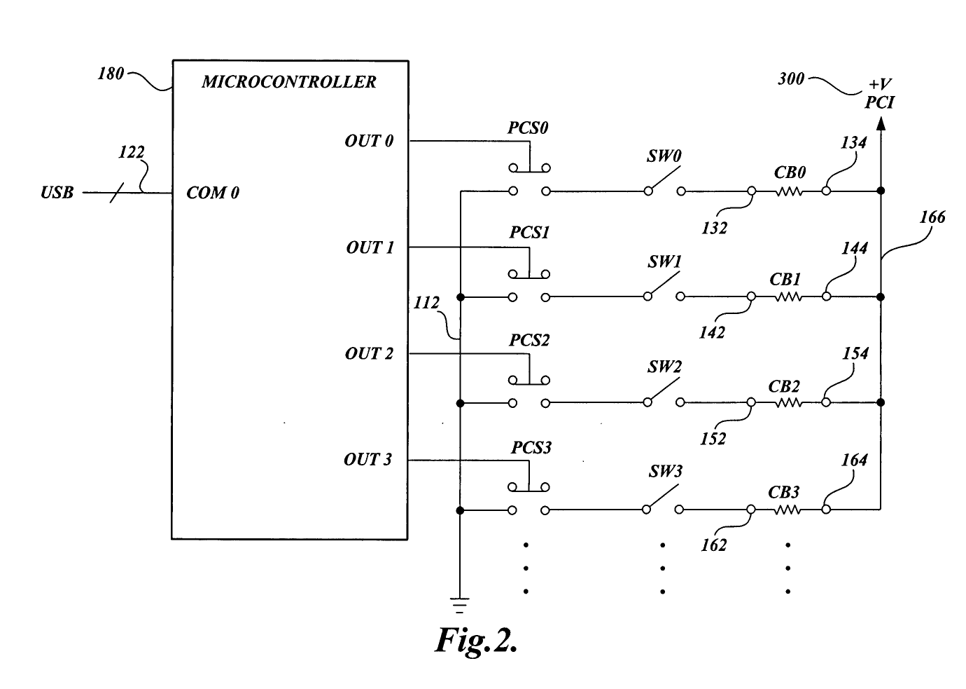

The two power lines, i.e., traces, 112 and 166 of the PCI bus 111 are separately identified. One of the power traces is a ground power trace 112 and the other is a “hot” power trace 166. As shown in FIG. 2, which illustrates a portion of the exemplary embodiment of the invention described herein, the ground power trace 112 of the PCI bus is connected to power supply terminals 132, 142, 152, 162 . . . of each of the backplane connectors 130, 140, 150, 160 . . . via both manual switches (optional) and electrically controlled switches, connected in series. More specifically, one of the power supply terminals (i.e., the ground terminal) of each of the backplane connectors is connected to the ground power trace 112 via a manual switch, designated SW0, SW1, SW2, SW3 . . . and an electrically controlled switch, designated PCS0, PCS1, PCS2, PCS3 . . . .

In the embodiment illustrated in FIGS. 1 and 2, SW0 and PCS0 connect the ground power trace 112 to the ground terminal 132 of the first backplane connector 130; SW1 and PCS1 connect the ground power trace 112 to the ground terminal 142 of a second backplane connector 140; SW2 and PCS2 connect the ground power trace 112 to the ground terminal 152 of a third backplane connector 150; SW2 and PCS2 connect the ground power trace 112 to the ground terminal 162 of the fourth backplane connector 160, etc.

FIGS. 1 and 2 also illustrate a plurality of circuit boards, such as PCI cards, designated CB0, CB1, CB2, CB3 . . . coupled to related backplane connectors 130, 140, 150, 160 . . . . The circuit boards, i.e., CB0, CB1, CB2, CB3 . . . , are illustrated pictorially in FIG. 1 and diagrammatically as a simple resistor connected between the ground power terminals 132, 142, 152, 162 . . . of a related backplane connector 130, 140, 150, 160 . . . and the hot power terminals 134, 144, 154, 164 . . . . The hot power terminals are connected to the hot power trace 166 of the backplane bus.

The circuit boards each include a plurality of edge connectors 131 that contact the terminals 133 of related backplane connectors, when the circuit boards are suitably positioned in slots defined by the backplane connectors. Two of the terminals 132/134, 142/144, 152/154, 162/164 . . . are connected to the ground and hot power traces 112 and 166 of the PCI bus 111. Other terminals are connected to the signal traces 113 of the PCI bus 111.

The optional manual switches, i.e., SW0, SW1, SW2, SW3 . . . , are shown in FIG. 2 as single pole double throw switches having open and closed states. When in the closed state, current can flow through the manual switches and when in the open state, current does not flow through the switches. The open/closed state of the electrically controlled switches, i.e., PCS0, PCS1, PCS2, PCS3 . . . , is determined by the state of electronic control signals. As noted above, the manual and electrically controlled switches are connected in series. Thus, both switches connected to the ground terminal of a related backplane connector must be closed for the ground terminal to be connected to the ground power trace 112. Various types of electrically controlled switches can be used, for example, silicon controlled rectifiers (SCRs), transistor switches, relays, etc.

Power to the power terminals (hot and ground) of each backplane connector can be turned on and off using either the related manual switch or the related electrically controlled switch. When the power to the power terminals of a backplane connector is turned off, the circuit board plugged into the backplane connector is decoupled from the PCI bus on the backplane by being powered off. Powered off circuit boards will not respond to instructions received from the computing device 200 via the PCI bus or send data to the computer via the PCI bus. Thus, decoupled circuit boards effectively have no impact on the computing device 200 or circuit boards not decoupled from PCI bus. Test software instructions sent to the circuit boards via the backplane bus are not received by and do not affect the decoupled circuit boards. Thus, for example, if SW0 is open, power to the related backplane connector 130 is turned off. As a result, CB0, which is plugged into the backplane connector 130 related to PCS0, is decoupled, whereby CB0 does not respond to computer software instructions sent to CB0, CB1, CB2, CB3 . . . via the PCI bus, or send data to the computing device via the PCI bus. Likewise, if SW0, rather than PCS0 is open (or both are open).

One end of the USB cable 230 is connected to the USB connector 220 on the computing device 200 and the other end of the USB cable 230 is connected to a USB connector 120 on the backplane 100. The backplane USB connector 120 is connected by a USB bus 122 to a microprocessor 180 mounted on the backplane 100. Those skilled in the art will appreciate that a microprocessor is an integrated circuit that includes the logic, memory, input, output, timing, etc., required to control particular kinds of electric circuits and systems.

As shown schematically in FIG. 2, the outputs of the microprocessor 180 are connected to the control inputs of PCS0, PCS1, PCS2, PCS3 . . . . The state of the outputs of the microprocessor control the open/close states of the electrically controlled switches, i.e., PCS0, PCS1, PCS2, PCS3 . . . to which the outputs are connected.

A software program running on the computing device 200 sends instructions to the microprocessor 180 to cause the microprocessor to close or open the electrically controlled switches, i.e., PCS0, PCS1, PCS2, PCS3 . . . and, thus, control the application of power to the power terminals of the backplane connectors. More specifically, as shown in FIG. 2, the microprocessor 180 has one input, designated COM 0, and multiple outputs, designated OUT 0, OUT 1, OUT 2, OUT 3 . . . COM 0 is connected to the USB connector 120 mounted on the backplane 100 via the USB bus 122, as described above. Each output controls the state of one of the electrically controlled switches. In other implementations, an output may control the state of more than one electrically controlled switch. Thus, applying one output to control one electrically controlled switch should be construed as exemplary and not limiting. In the embodiment illustrated in FIG. 2, OUT 0 controls the state of PCS0; OUT 1 controls the state of PCS1 144; OUT 2 controls the state of PCS2 154; OUT 3 controls the sate of PCS3 164;

As will be readily appreciated by those skilled in the art and others, electronic or electrical devices or combinations of electronic or electrical devices may be used in place of the microprocessor 300. Thus, the inclusion of a single microprocessor 300 in the exemplary embodiment of the invention described herein should be construed as exemplary and not limiting. Likewise, as noted above, electrically controlled switches should be construed broadly as covering various types of electrical switches such as relays, as well as more classic electronic switches, such as SCRs, TRIACs, transistor switches, and the like.

As previously described, the manual switches, which are optional, and the electrically controlled switches are connected in series on a one-to-one basis. Thus, both a manual switch, e.g., SW0, and its associated electrically controlled switch, i.e., PCS0, must be closed in order for current to flow through the power terminals of the related backplane connector 130 to the related circuit board, i.e., CB0. If either the manual switch, i.e., SW0, or its associated electrically controlled switch, i.e., PCS0, are open, current is unable to flow through the power terminals of the related backplane connector 130 to the related circuit board, i.e., CB0. When either switch of the pair of switches is open, the related circuit board is decoupled from the PCI bus and, thus, is inaccessible (i.e., will not respond to instructions from or send data to) to components connected to the PCI bus such as the computing device 200.

The computing device 200 depicted in FIG. 1, sends instructions through the USB bus 122 to COM 0 of the microprocessor 180. The microprocessor 180 decodes the instructions. The decoded instructions cause the microprocessor output ports, i.e., OUT 0, OUT 1, OUT 2, OUT 3 . . . to send enable/disable or more precisely open/close instructions to the electrically controlled switch, i.e., PCS0, PCS1, PCS2, PCS3 . . . connected to the output port. If an output port, i.e., OUT 0, generates a disable instruction, the switch to which the port is connected, i.e., PCS0, is opened. If the switch, i.e., PCS0, is open, no current is able to flow through the power terminals to the associated backplane connector, i.e., CB0. As noted above, circuit boards plugged into the unpowered backplane connectors are decoupled from the PCI bus and thus are inaccessible to components connected to the PCI bus, such as the computing device 200. Alternatively, if the output port, i.e., OUT 0, generates an enable instruction, the switch to which this port is connected, i.e., PCS0, is closed. As a result, power is applied to the power terminals of the associated backplane connector, i.e., CB0, provided the related manual switch, i.e., SW0, is also closed.

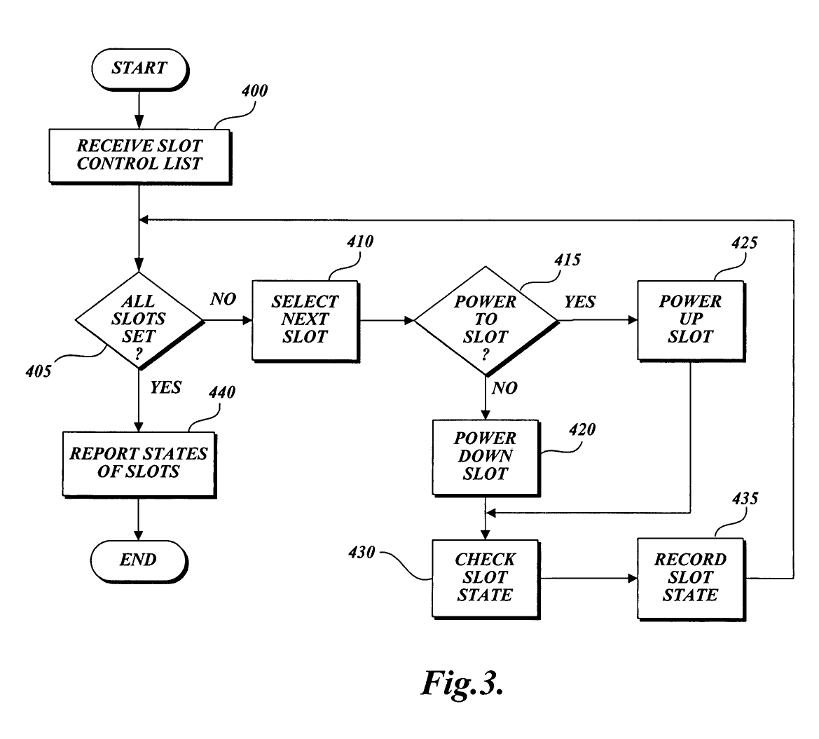

As noted above, the microprocessor 180 receives instructions from a computer program running on the computing device 200, such as a program for testing the operation of personal computer sound cards, for example. The instructions are sent to the microprocessor 180 through the USB computing device connector 220, the USB cable 230, USB backplane connector 120, and finally the USB bus 122. FIG. 3 is an exemplary functional flow diagram showing how the microprocessor 180 functions in response to instructions received from the computer device 200. The flow begins at block 400 where the microprocessor 180 receives a slot, i.e., backplane connector, control list. At block 405, a check is done to find out if all slots in the slot list have been set in accordance with the slot control list, i.e., if the open/closed states of PCS0, PCS1, PCS2, PCS3 . . . are in accordance with the slot control list. This could be accomplished by comparing the slot control list with a record of the previously set states of PCS0, PCS1, PCS2, PCS3 . . . stored in memory. Alternatively, or if the slots are not set correctly, the slots could be sequenced through and the status of PSC0, PCS1, PCS2, PCS3, sequentially set in the manner shown in FIG. 3. On initialization, i.e., without going through the block 405 check, or if all slots have not been correctly set, the next slot in the slot list is selected at block 410. At block 415, the intended state of the slot, i.e., powered or unpowered, is determined. If the intended state of the slot is powered, the flow goes to block 425 where the slot is powered up, i.e., the related electrically controlled switch is closed. If the intended state of the slot is unpowered, the flow goes to block 420 where the slot is powered down, i.e., the related electrically controlled switch is opened. Regardless of which path is followed, the actual state of the slot is checked at block 430. At block 435, the slot state is recorded in memory. The flow then returns to block 405. At block 405, a check is done to find out if all slots in the slot list have been set. If all slots have been set, the flow proceeds to block 440 where the states of the slots are reported. Then, the flow ends.

While the preferred embodiment of the invention has been illustrated and described, it will be appreciated that various changes can be made therein without departing from the spirit and scope of the invention. For example, as noted to some extent above by . . . although four backplane connectors are shown in the exemplary embodiment described herein, more or fewer backplane connectors could be used. Further, as also noted above to some extent, the functions illustrated in FIG. 3 and described above can be accomplished in various ways. Moreover, the electronic switches could be incorporated into the microprocessor architecture. Also, the manual switches, which are optional, could be connected in parallel, rather than series with the electronic switches if desired. Hence, within the scope of the appended claims, it is to be understood that the invention can be practiced otherwise than as specifically described herein.

The embodiments of the invention in which an exclusive property or privilege is claimed are defined as follows:

1. Apparatus for controlling the selective testing of a plurality of circuit boards comprising:
a backplane including a bus;
a plurality of backplane connectors mounted on said backplane each suitable for receiving a circuit board, each of said backplane connectors including terminals connected to the traces of said bus and suitable for connecting to the terminals of a circuit board received by a backplane connector, said terminals including power terminals for supplying power to circuit boards received by said backplane connectors; and
a controller for controlling the application of power to said power terminals such that selected ones of said power terminals receive power and others do not receive power thereby controlling the coupling of circuit boards received by said backplane connectors to said bus.

2. Apparatus as claimed in claim 1 wherein said controller includes electrically controlled switches for controlling the application of power to said power terminals and a microprocessor for controlling the state of said electrically controlled switches.

3. Apparatus as claimed in claim 2 including manual switches for controlling the application of power to said power terminals.

4. Apparatus as claimed in claim 3 wherein said electrically controlled switches and said manual switches are connected in series.

5. Apparatus as claimed in claim 3 wherein a single electrically controlled switch and a single manual switch are connected to the power terminals of each of said backplane connectors.

6. Apparatus as claimed in claim 5 wherein each single electrically controlled switch and said single manual switch pair are connected in series.

7. Apparatus as claimed in claim 1 wherein said backplane bus is a PCI bus.

8. A method of controlling the selective testing of a plurality of circuit boards connected to backplane connectors mounted on a backplane that includes a backplane bus connected to the terminals of the backplane connectors, comprising:
generating a control signal suitable for identifying which of the plurality of circuit boards are to be tested and which of the plurality of circuit boards are not to be tested; and
controlling the application of power to the power terminals of said backplane connectors in accordance with said control signals.

9. The method claimed in claim 8 wherein controlling the application of power to the power terminals of said backplane connectors in accordance with said control signal includes:
analyzing said control signal to determine which of the plurality of circuit boards are to be tested and which of the plurality of circuit boards are not to be tested; and
applying power only to the backplane connectors connected to the circuit boards that are to be tested.

10. The method claimed in claim 9 wherein analyzing said control signal to determine which of the plurality of circuit boards are to be tested and which of the circuit boards are not to be tested includes determining if the application of power to said backplane connectors corresponds to said control signal.

11. The method claimed in claim 10 wherein if said application of power to said backplane connectors does not correspond to said control signal, the power to said backplane connectors is set in accordance with said control signal.

12. The method claimed in claim 11, wherein the power to said backplane connectors is set in a sequential manner.

13. The method claimed in claim 11 wherein the application of power to said backplane connectors is set by controlling the open/closed state of electrically controlled switches that control the application of power to said backplane connectors.

14. A microprocessor containing computer executable instructions that when executed control the application of power to the power terminals of a plurality of backplane connectors by
identifying which of the plurality of backplane connectors are to be powered; and
controlling the application of power to the power terminals of the identified ones of the plurality of backplane connectors.

15. A microprocessor as claimed in claim 14 wherein identifying which of the plurality of backplane connectors are to be powered comprises analyzing a control signal that contains information identifying which of the plurality of backplane connectors are to be powered.

16. A microprocessor as claimed in claim 15 wherein said analysis comprises determining the identity of the plurality of backplane connectors that are to be powered and generating individual control signals for each backplane connector whose state is determined by the identity of the plurality of backplane connectors that are to be powered.

17. A microprocessor as claimed in claim 14 wherein controlling the application of power to the power terminals of the identified ones of said plurality of backplane connectors comprises controlling the open/closed state of electrically controlled switches that control the application of power to the power terminals of the backplane connectors.

18. A microprocessor as claimed in claim 16 wherein identifying which of the plurality of backplane connectors are to be powered comprises analyzing a control signal that contains information identifying which of the plurality of backplane connectors are to be powered.

19. A microprocessor as claimed in claim 18 wherein said analysis comprises determining the identity of the plurality of backplane connectors that are to be powered and generating individual control signals for each backplane connector whose state is determined by the identity of the plurality of backplane connectors that are to be powered.
